(19) United States
(12) Patent Application Publication
(10) Pub. No.: US 2012/0080137 A1
(43) Pub. Date: Apr. 5, 2012

(54) MANUFACTURING METHOD OF CIRCUIT BOARD

(76) Inventor: HUNG-MING LIN, Yonghe City (TW)

(21) Appl. No.: 12/946,343

(22) Filed: Nov. 15, 2010

(30) Foreign Application Priority Data
Oct. 1, 2010 (TW) 99133494

(51) Int. Cl. H05K 3/46; H05K 3/10; C25D 1/20

(52) U.S. Cl. 156/150; 205/78

(57) ABSTRACT

A manufacturing method of a circuit board. First, an electrode mold having a conductive circuit pattern is made, and then a conductive circuit metal layer is formed by means of electroplating on the electrode mold. The conductive circuit metal layer is transferred and joined with the dielectric layer to constitute a basic circuit board. After the conductive circuit metal layer is transferred to the dielectric layer, the electrode mold can be reused for electroplating, so that the conductive circuit metal layer may be formed again for the next basic circuit board. The manufacturing method provided herein may significantly reduce the manufacturing time and raising the product yields of the circuit board, and has the advantages of lower cost and environmental friendly.

### BACKGROUND OF THE INVENTION

1. Field of the Invention

The present invention relates to a manufacturing method of a circuit board, and more particularly to a manufacturing method in which an electrode mold of a conductive circuit pattern is first made, then by electroplating, a conductive circuit metal layer is formed on the electrode mold, and then the conductive circuit metal layer is transferred to a dielectric layer.

2. Description of the Prior Art

The manufacturing techniques of circuit boards can be divided into additive and subtractive processes. The present developments of additive processes are mainly directed to approaches adopting printing electronic circuits directly on an insulating substrate with a functional ink. Unsolved issues of these approaches are being endeavored by many countries, but there is no known approach in production for the market. Subtractive processes, on the other hand, are currently the mainstream techniques that have matured from developments. One well known copper foil etching approach uses a board having a laminated copper foil as a substrate, forms anti-etching circuit patterns on the copper foil by means of screen printing or photo imaging, and removes the non-circuit portion by means of chemical etching to get the circuits. In order to obtain a basic circuit board, the process involves pre-processing the copper foil substrate, coating a light-sensitive material, exposing, developing, etching, and removing the coating, etc., and is therefore a complicated process undergoing high temperature, high humidity, strong acid and strong base treatments. The basic circuit board resulted from this method is shown in FIG. 1, wherein the conductive circuit 10 is adhesively joined to the dielectric layer 12 only at a single bottom surface 14.

A US patent application publication 20040168312 discloses a printed circuit board with inlaid outer layer circuit and the manufacturing method thereof. Primarily, it forms conductive circuits on a release mold board by means of metallization, light scribing or optical molding, and pattern electroplating, and transfers the circuit patterns to a dielectric layer by means of laminating. However, this manufacturing method requires for each circuit board repeating the foregoing metallization, light scribing or optical molding, and pattern electroplating processing steps to form a group of conductive circuits transferred to the dielectric layer, and is therefore complicated and costly.

A US patent application publication 20080098596 discloses a method for forming transcriptional circuits and a method for manufacturing a circuit board which involves forming an intaglio pattern corresponding to a circuit pattern on a mold board, filling the conductive pattern into the intaglio pattern, and by pressing a carrier onto the mold board transcribing the conductive material onto the mold board. However, during the step of pressing the carrier onto the mold board to transcribe the conductive material, the surface of the mold board is susceptible to be damaged from being in contact with the carrier, which may adversely impact the manufacture of the next conductive pattern. Therefore, the mold board reutilization for this manufacturing method is low.

### SUMMARY OF THE INVENTION

In order to solve the foregoing problems, one objective of the present invention is to provide a manufacturing method of a circuit board which does not employ the traditional approaches performing image transferring, etching, laminating to the copper foil substrate; therefore, not only the product yield is raised, but also the cost is lowered, and the usage of water, electricity and various chemicals are reduced, thereby significantly reducing the harmful effects to the environment.

According to an embodiment, the manufacturing method of a circuit board includes the following steps. First, a first electrode mold is made, the upper surface thereof includes a first conductive circuit pattern and the first patterned groove, and the first patterned groove has a first dielectric layer disposed therein. Then the first electrode mold is electroplated so that a conductive circuit metal layer is formed on the first conductive circuit pattern. Thereafter, a dielectric layer is disposed on the first electrode mold, and the conductive circuit metal layer is transferred to at least a surface of the dielectric layer. Finally, the first electrode mold is separated from the dielectric layer, and the dielectric layer with the conductive circuit metal layer thereon constitutes a circuit board.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1 is a schematic diagram illustrating a circuit board manufactured according to the prior art;

FIG. 2a to FIG. 2g are sectional diagrams schematically illustrating the manufacturing method of the circuit board according to an embodiment of the present invention;

FIG. 3 is a sectional diagram schematically illustrating the circuit board according to an embodiment of the present invention;

FIG. 4 is a sectional diagram schematically illustrating the circuit board according to another embodiment of the present invention; and

FIG. 5a to FIG. 5e are sectional diagrams schematically illustrating the manufacturing method of the conductive through holes according to an embodiment of the present invention.

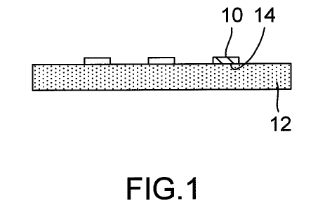

### DESCRIPTION OF THE PREFERRED EMBODIMENT

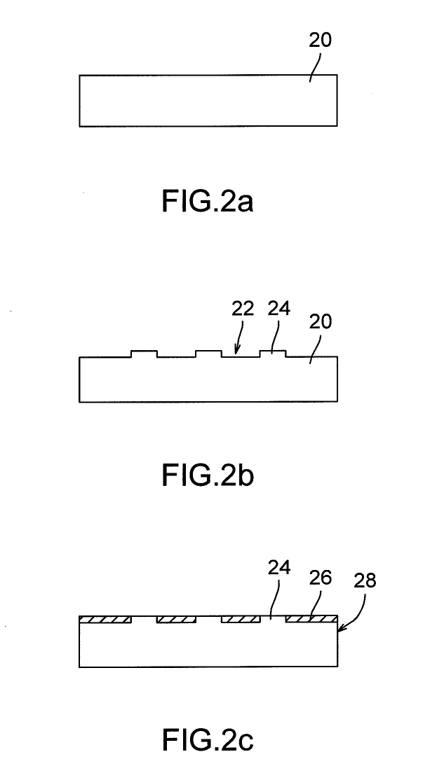

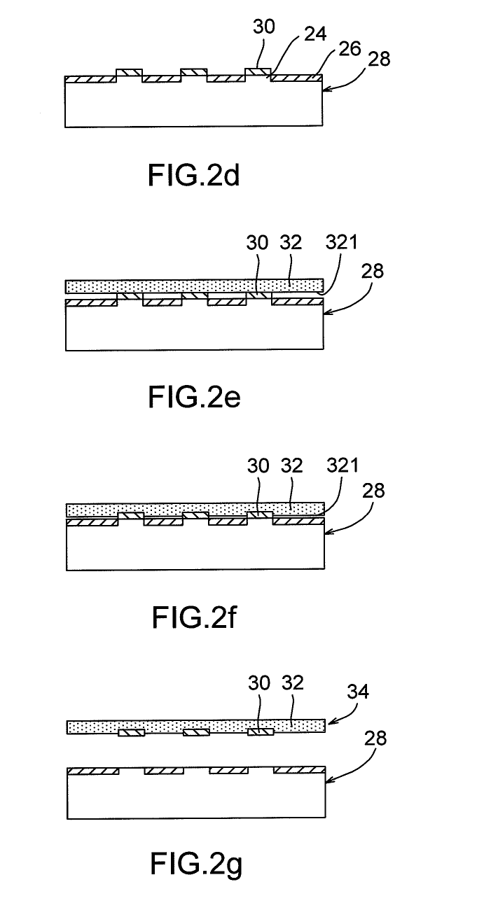

FIG. 2a and FIG. 2g are sectional diagrams schematically illustrating the manufacturing method of the circuit board according to an embodiment. As illustrated in FIG. 2a, first, an electrode mold material 20 is prepared. The electrode mold material 20 is a conductive material and is also a material hard to be plated, preferably a material that would have a lower bonding force with the metal being electroplated to the material subsequently. Common selections of the material include conductive glass, stainless steel, graphite plate and so on.

Next, a circuit pattern is transferred to the electrode mold material 20. By a black-line engraving method, the circuit pattern is engraved to the electrode mold material 20, as shown in FIG. 2b, forming the first patterned groove that delineates a first conductive circuit pattern 24. Here the black-line engraving method may include machining, laser scribing or etching, etc.

In a further step, a first insulating layer 26 is formed in the first patterned groove 22 to finish the process of making a first electrode mold 28. As illustrated in FIG. 2c, the upper surface of the first electrode mold 28 includes a first conductive circuit pattern 24, and an insulating area formed by the first insulating layer 26. The method of forming the first insulating layer 26 may include oxidizing the first patterned groove 24 or filling an insulating material to the first patterned groove 22.

Thereafter, the first electrode mold 28 is electroplated. The first conductive circuit pattern 24 would be attached with metal, thereby forming a conductive circuit metal layer 30. As shown in FIG. 2d, the conductive circuit metal layer 30 protrudes from the surface of the first insulating layer 26.

Next, the first electrode mold 28 finished with electroplating for the conductive circuit metal layer 30 is taken out and a first dielectric layer 32 is disposed on the first electrode mold 28. As illustrated in FIG. 2e, a surface 321 of the dielectric layer 32 is joined to the conductive circuit metal layer 30, wherein the dielectric layer 32 is an adhesive-bonded dielectric film consists of polymers.

In a further step, the conductive circuit metal layer 30 of the first electrode mold 28 is embedded within the dielectric layer 32, as shown in FIG. 2f, and is transferred to the surface 321 of the dielectric layer 32.

Finally, the first electrode mold 28 is separated from the dielectric layer 32, as shown in FIG. 2g, and the resulting dielectric layer 32 with the conductive circuit metal layer 30 constitutes a one layer basic circuit board 34. In another aspect, the first electrode mold 28 separated here may be reused for the electroplating process as shown in FIG. 2d and the conductive circuit metal layer 30 can be formed again for the next basic circuit board 34.

Continuing the above description, since the electrode mold material 20 used has a lower bonding force with the electroplated metal, the conductive circuit metal layer 30 after electroplating can be easily and completely transferred to the dielectric layer 32. The number of metal layers electroplated, the kind, and the thickness can be decided in accordance with the subsequent need of the product. Also, to adapt to the usage environment of the product, the voltage and current for electroplating can be adjusted to control the grain and the surface roughness of the conductive circuit metal layer 30.

In another aspect, referring still to FIG. 2e and FIG. 2f, a method for transferring the conductive circuit metal layer 30 according to an embodiment includes first disposing a colloid (not shown in the figure) on the surface of the dielectric layer 32 so that the conductive circuit metal layer 30 can join adhesively to the surface of the dielectric layer 32 and then be transferred to the dielectric layer 32. In another embodiment, after the dielectric layer 32 joins adhesively to the conductive circuit metal layer 30, the dielectric layer 32 is heated to a temperature above a glass transformation temperature and a pressure is applied so that the conductive circuit metal layer 30 would sink into the dielectric layer 32. After the temperature has dropped below the glass transformation temperature, the first electrode mold 28 and the dielectric layer 32 are separated, and by then, the conductive circuit metal layer 30 has already been transferred to the dielectric layer 32.

In the manufacturing method of the circuit board of the present invention, there is no need to perform image transferring, etching and laminating, etc, on the copper foil substrate as in the traditional manufacturing process; instead, the circuit pattern is directly manufactured on the first electrode mold, through electroplating, the circuit pattern is metallized and a conductive circuit metal layer is formed, and through laminating, the conductive circuit metal layer is transferred and embedded into the dielectric layer. Compared to the traditional process, the present invention saves a lot of processing steps, significantly reducing the time required, enhancing the product yield, and conserving water, electricity and chemicals and is therefore of great help to cost reduction and environmental protection.

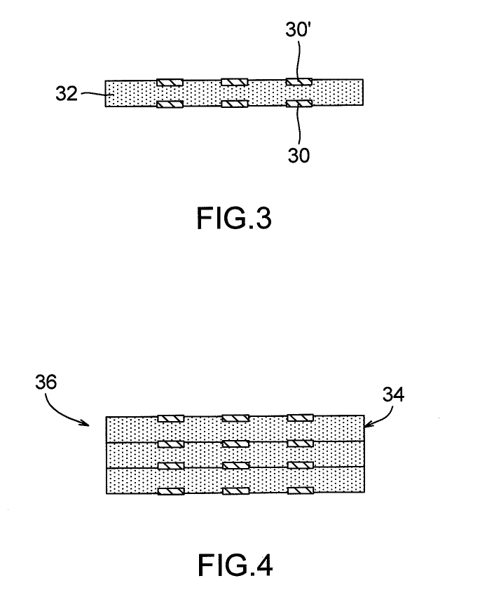

On the other hand, in the present invention, as shown in FIG. 3, both sides of the dielectric layer 32 can have adhesively joined conductive circuit metal layers 30, 30′ for manufacturing a double sided circuit board. As shown in FIG. 4, the aforementioned basic circuit board 34 or the double sided circuit board may be stacked to form a double layer or multi-layer circuit board 36. Generally speaking, when making leads of a chip, a single layer circuit board may be used for subsequent processing, and when making a connector, a single layer, double layer or multi-layer circuit board may be used upon required for subsequent processing.

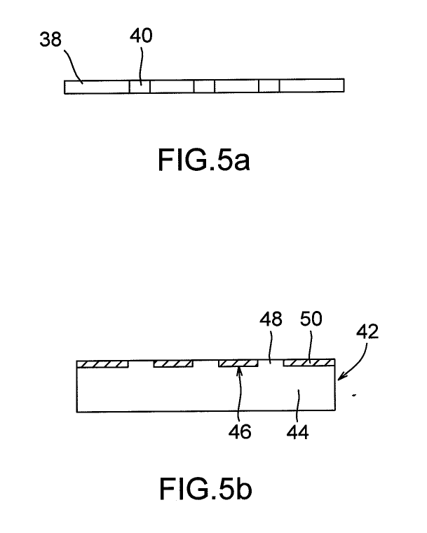

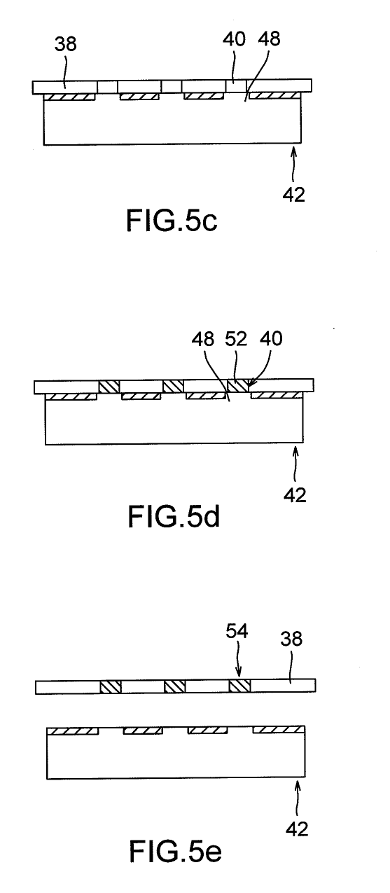

Continuing the above description, when both sides of the circuit board have conductive circuit metal layers, conductive through holes are required for electrical connection. FIG. 5a to FIG. 5e are sectional diagrams schematically illustrating a manufacturing method of the conductive through holes according to an embodiment. As illustrated in FIG. 5a, a plurality of through holes 40 are formed on a circuit board 38. Then, a second electrode mold 42 is made according to the previously described method illustrated in FIG. 2a to FIG. 2c. A second patterned groove 46 is formed on an electrode mold material 44, and delineates the second conductive circuit pattern 48. A second dielectric layer 50 is formed in the second patterned groove 46, and a second electrode mold 42 as shown in FIG. 5b is finished. Note that the position of the second conductive circuit pattern 48 corresponds to the through holes 40 on the circuit board 38. Thereafter, as illustrated in FIG. 5c, the second electrode mold 42 and the circuit board 38 are laminated, and the second conductive circuit pattern 48 corresponds to the through holes 40. Then, as shown in FIG. 5d, electroplating is performed so that an electroplated metal 52 is deposited in the through holes 40, and finally, the second electrode mold 42 is separated from the circuit board 38 as shown in FIG. 5e, and the conductive through holes are finished.

In summary, the manufacturing method of the circuit board of the present invention has the following advantages:

1. the present invention provides a process free of many processing steps required in the traditional process, thereby enhancing product yield, lowering cost, decreasing the usage for water, electricity and chemicals, and significantly reducing the harmful impacts to the environment.

2. the conductive circuit metal layer is embedded into the dielectric layer: therefore, three of its surfaces are adhesively joined to the dielectric layer, effectively increasing the attaching strength.

3. stacking process is performed on the electrode mold: since the electrode mold is made of a material that is firm, less susceptible to deformation, and not easily expand or contract, misalignment issues during stacking for double layer or multi-layer circuit board are reduced.

4. overall thickness is more accurately controlled: since each layer is individually made from a conductive circuit metal layer and a dielectric layer, the overall thickness of the product can be definitely controlled.

5. the internal bubbles are reduced and the surface is flatter: because the conductive circuit metal layer is embedded in the dielectric layer, the height differences resulted from the topography of circuit distribution is reduced, which helps reducing the bubbles generated during the stacking at the inner layers, and ameliorating the printing quality of the solder-resistant green paint at the outer layer.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A manufacturing method of a circuit board comprising:
making a first electrode mold, an upper surface thereof comprising a first conductive circuit pattern and a first patterned groove, the first patterned groove having a first insulating layer disposed therein;
performing electroplating to the first electrode mold to form a first conductive circuit metal layer on the first conductive circuit pattern;
disposing a dielectric layer on the first electrode mold and transferring the conductive circuit pattern to at least a surface of the dielectric layer; and
separating the first electrode mold and the dielectric layer, resulting in the dielectric layer with the conductive circuit metal layer constituting a basic circuit board.

2. The manufacturing method of the circuit board according to claim 1, wherein the method of manufacturing the electrode mold comprises:
preparing an electrode mold material;
forming the first patterned groove on the electrode mold material by means of a black-line engraving method to delineate the first conductive circuit pattern; and
disposing the first insulating layer in the first patterned groove.

3. The manufacturing method of the circuit board according to claim 2, wherein the method of forming the first insulating layer comprising oxidizing the first patterned groove or filling an insulating material into the first patterned groove.

4. The manufacturing method of the circuit board according to claim 2, wherein the black-line engraving method comprises machining, laser scribing or etching.

5. The manufacturing method of the circuit board according to claim 2, wherein the electrode mold material has a low bonding force with the conductive circuit metal layer.

6. The manufacturing method of the circuit board according to claim 5, wherein the electrode mold material comprises stainless steel, conductive glass or graphite.

7. The manufacturing method of the circuit board according to claim 1, wherein the conductive circuit metal layer on the first conductive circuit pattern protrudes from the insulating layer.

8. The manufacturing method of the circuit board according to claim 1, wherein the method of transferring the conductive circuit metal layer comprises:
disposing a colloid on at least a surface of the dielectric layer; and
joining the surface of the dielectric layer disposed with the colloid to the conductive circuit metal layer for the conductive circuit metal layer to adhesively attached to the dielectric layer.

9. The manufacturing method of the circuit board according to claim 1, wherein the method for transferring the conductive circuit metal layer comprises:
joining the dielectric layer to the conductive circuit metal layer;
heating the dielectric layer to a glass transformation temperature;
applying a pressure so that the conductive circuit metal layer sinks into the dielectric layer; and
lowering the temperature of the dielectric layer.

10. The manufacturing method of the circuit board according to claim 1, wherein the first electrode mold can be reused.

11. The manufacturing method of the circuit board according to claim 1, further comprising stacking a plurality of the basic circuit boards to manufacture a double layer or multi-layer circuit board.

12. The manufacturing method of the circuit board according to claim 1, wherein the conductive circuit metal layers are transferred to the two opposite surfaces of the dielectric layer to manufacture a double sided circuit board.

13. The manufacturing method of the circuit board according to claim 12, further comprising forming a plurality of conductive through holes on the double sided circuit board.

14. The manufacturing method of the circuit board according to claim 11, wherein the method of making the conductive through holes comprises:
disposing a plurality of through holes on the double sided circuit board;
making a second electrode mold, a surface thereof comprising a second conductive circuit pattern and a second patterned groove, the second patterned groove being correspondingly positioned with respect to the through holes and the second patterned groove having a second insulating layer disposed therein; and
laminating the second electrode mold and the circuit board and the second conductive circuit pattern being correspondingly positioned with respect to the through holes, and performing electroplating to deposit an electroplated metal in the through holes whereby the conductive through holes are formed.
